(19) United States
(12) Patent Application Publication
(10) Pub. No.: US 2024/0282724 A1
(43) Pub. Date: Aug. 22, 2024

(54) ANTENNA-INTEGRATED HIGH-FREQUENCY SEMICONDUCTOR PACKAGE AND METHOD OF MANUFACTURING SAME

(71) Applicant: KOREA ELECTRONICS TECHNOLOGY INSTITUTE, Seongnam-si (KR)

(72) Inventors: Jong Min YOOK, Seongnam-si (KR); Je In YU, Seoul (KR); Dong Su KIM

(73) Assignee: KOREA ELECTRONICS TECHNOLOGY INSTITUTE, Seongnam-si (KR)

(21) Appl. No.: 18/439,938

(22) Filed: Feb. 13, 2024

(30) Foreign Application Priority Data
Feb. 16, 2023 (KR) 10-2023-0020767

(51) Int. Cl. H01L 23/66; H01L 23/00; H01L 23/367; H01L 23/498

(52) U.S. Cl. CPC H01L 23/66; H01L 23/367; H01L 23/49827; H01L 24/32; H01L 2223/6677; H01L 2224/32225; H01L 2924/181

(57) ABSTRACT

An antenna-integrated high-frequency semiconductor package, including a substrate including a recess concave on a first surface and a first through-hole penetrating from the first surface to a second surface, a ground layer configured to cover the first surface of the substrate and the recess, a semiconductor chip mounted on the ground layer of the recess, an insulating layer configured to entirely cover the substrate, the ground layer, and the semiconductor chip, and a conductive layer formed on the insulating layer, the conductive layer including an electrode pattern connected to the semiconductor chip, an antenna formed on a second surface of the insulating layer, and a signal via configured to transmit an electrical signal between the electrode pattern and the antenna through a second through-hole formed in the first through-hole to penetrate from the first surface to the second surface of the insulating layer.

### CROSS REFERENCE TO RELATED APPLICATION

This patent document claims the priority and benefits of Korean Patent Application No. 10-2023-0020767, filed Feb. 16, 2023, the entire contents of which is incorporated herein by reference for all purposes.

### TECHNICAL FIELD

The present disclosure relates to an antenna-integrated high-frequency semiconductor package and a method of manufacturing the same.

### BACKGROUND

With the development of mobile communication technology and the trend toward miniaturization of electronic devices, packages in the form in which a semiconductor chip and an antenna are integrated in one package are being developed. As the signal frequency increases, the size of the antenna becomes smaller, making it easier to form an antenna in a package. However, as the signal frequency increases, the signal transmission process may be greatly affected by parasitic components. Developing a package structure to satisfy all of these technical constraints is a challenging task.

### SUMMARY

The present disclosure is intended to provide an antenna-integrated high-frequency semiconductor package and a method of manufacturing the same.

The present disclosure provides an antenna-integrated high-frequency semiconductor package, including a substrate having a first surface and a second surface opposing the first surface and including a recess concave in a direction from the first surface to the second surface and a first through-hole penetrating from the first surface to the second surface, a ground layer configured to cover the first surface of the substrate and the recess, a semiconductor chip mounted on the ground layer of the recess, an insulating layer configured to entirely cover the substrate, the ground layer, and the semiconductor chip, and a conductive layer formed on the insulating layer, in which the conductive layer may include an electrode pattern formed on a first surface of the insulating layer and connected to the semiconductor chip, an antenna formed on a second surface of the insulating layer, and a signal via configured to transmit an electrical signal between the electrode pattern and the antenna through a second through-hole formed in the first through-hole to penetrate from the first surface to the second surface of the insulating layer.

In one embodiment, the antenna may be designed in consideration of a first distance from the ground layer formed on the first surface of the substrate to the second surface of the insulating layer and a second distance from the ground layer formed on an inner surface of the recess to the second surface of the insulating layer.

In one embodiment, the antenna-integrated high-frequency semiconductor package may further include a shield formed on an inner surface of the first through-hole by forming the ground layer to cover the inner surface of the first through-hole, and the signal via and the shield may be formed as coaxial vias.

In one embodiment, the antenna-integrated high-frequency semiconductor package may further include a third through-hole formed to penetrate from the first surface to the second surface of the substrate, a ground via formed on an inner surface of the third through-hole by forming the ground layer to cover the inner surface of the third through-hole, and a ground ring connected to the ground via and formed in a ring shape surrounding the antenna by forming the ground layer to cover the second surface of the substrate in a ring shape.

In one embodiment, the antenna-integrated high-frequency semiconductor package may further include a ground pattern configured to connect the ground layer and an external circuit to each other by passing through the first surface of the insulating layer and dissipate heat generated by the semiconductor chip to an external circuit.

In addition, the present disclosure provides a method of manufacturing an antenna-integrated high-frequency semiconductor package, including preparing a substrate having a first surface and a second surface opposing the first surface, processing the substrate to form a recess concave in a direction from the first surface to the second surface of the substrate and a first through-hole penetrating from the first surface to the second surface, forming a ground layer with an electrically conductive material to cover the first surface of the substrate and the recess, mounting a semiconductor chip in the recess covered with the ground layer, forming an insulating layer that entirely covers the substrate, the ground layer, and the semiconductor chip, processing the insulating layer to form a pad exposure portion exposing a front pad of the semiconductor chip by removing part of the insulating layer and a second through-hole in the first through-hole to penetrate from the first surface to the second surface of the insulating layer, and forming a conductive layer with an electrically conductive material on the first surface and the second surface of the insulating layer and patterning the conductive layer, in which patterning the conductive layer may include forming an electrode pattern connected to the semiconductor chip by patterning a conductive layer formed on the first surface of the insulating layer and forming an antenna by patterning a conductive layer formed on the second surface of the insulating layer, and a signal via formed on an inner surface of the second through-hole may be connected to transmit an electrical signal between the electrode pattern and the antenna.

In one embodiment, in patterning the conductive layer, the antenna may be patterned in a shape designed in consideration of a first distance from the ground layer formed on the first surface of the substrate to the second surface of the insulating layer and a second distance from the ground layer formed on an inner surface of the recess to the second surface of the insulating layer.

In one embodiment, in forming the ground layer, a shield may be further formed on an inner surface of the first through-hole by forming the ground layer to cover the inner surface of the first through-hole, and in processing the insulating layer, the first through-hole and the second through-hole may be formed coaxially, so that the signal via and the shield may be formed coaxially.

In one embodiment, in processing the substrate, a third through-hole may be further formed to penetrate from the first surface to the second surface of the substrate, in forming the ground layer, a ground via may be formed on an inner surface of the third through-hole by forming the ground layer to cover the inner surface of the third through-hole, and the ground layer may be formed to cover the second surface of the substrate, and the method of manufacturing the antenna-integrated high-frequency semiconductor package may further include forming a ground ring to cover the second surface of the substrate in a ring shape by patterning the ground layer formed on the second surface of the substrate, after forming the ground layer.

In one embodiment, in processing the insulating layer, a ground exposure portion exposing part of the ground layer may be further formed by removing the first surface of the insulating layer, and in patterning the conductive layer, a ground pattern that connects the ground layer and an external circuit to each other and dissipates heat generated by the semiconductor chip to an external circuit may be further formed.

The features and advantages of the present disclosure will become more apparent from the following detailed description based on the accompanying drawings.

Before the present disclosure is described in more detail, it must be noted that the terms and words used in the present specification and claims should not be interpreted as being limited to typical meanings or dictionary definitions, but should be interpreted as having meanings and concepts relevant to the technical spirit of the present disclosure based on the rule according to which an inventor can appropriately define a concept of a term to best describe the method he or she knows for carrying out the disclosure.

According to the present disclosure, it is possible to minimize the size of a package while minimizing loss occurring while transmitting a signal to an antenna at a high frequency.

### BRIEF DESCRIPTION OF THE DRAWINGS

The above and other aspects, features, and other advantages of the present disclosure will be more clearly understood from the following detailed description taken in conjunction with the accompanying drawings, in which:

FIG. 1 is a plan view showing an antenna-integrated high-frequency semiconductor package according to an embodiment;

FIG. 2 is a cross-sectional view taken along line A-A′ of FIG. 1;

FIG. 3 is a plan view showing an antenna-integrated high-frequency semiconductor package further including a ground ring according to an embodiment;

FIG. 4 is a cross-sectional view taken along line B-B′ of FIG. 3;

FIGS. 5, 6, and 7 show steps of a process of manufacturing an antenna-integrated high-frequency semiconductor package according to an embodiment; and

FIGS. 8, 9, and 10 show steps of a process of manufacturing an antenna-integrated high-frequency semiconductor package according to an embodiment.

### DETAILED DESCRIPTION

Aspects, advantages, and features of the present disclosure will become more apparent from the following detailed description and embodiments taken in conjunction with the accompanying drawings, but the present disclosure is not necessarily limited thereto. In addition, when describing the present disclosure, if it is determined that a detailed description of related known technology may unnecessarily obscure the gist of the present disclosure, the detailed description will be omitted.

In assigning reference numerals to components in the drawings, it should be noted that identical components are assigned the same reference numerals as much as possible even if they are shown in different drawings, and similar components are assigned similar reference numerals.

Terms used to describe an embodiment of the present disclosure are not intended to limit the disclosure. It should be noted that singular expressions include plural expressions unless the context clearly dictates otherwise.

The drawings may be schematic or exaggerated to illustrate embodiments.

Herein, expressions such as “have,” “may have,” “include,” or “may include” refer to the existence of the corresponding feature (e.g., a numerical value, function, operation, or component such as a part), and do not rule out the existence of additional features.

Terms such as “one”, “other”, “another”, “first”, “second”, etc. refer to distinguishing one component from another, and the components are not limited by the above terms.

Terms indicating direction such as up, down, left, right, X-axis, Y-axis, Z-axis, etc. are only for convenience of explanation, and it should be understood that such terms may be expressed differently depending on the location of the observer or the location of the object.

The embodiments described herein and the accompanying drawings are not intended to limit the disclosure to specific embodiments. This disclosure should be understood to include various modifications, equivalents, and/or alternatives of the embodiments.

Hereinafter, a detailed description will be given of an embodiment of the present disclosure with reference to the attached drawings.

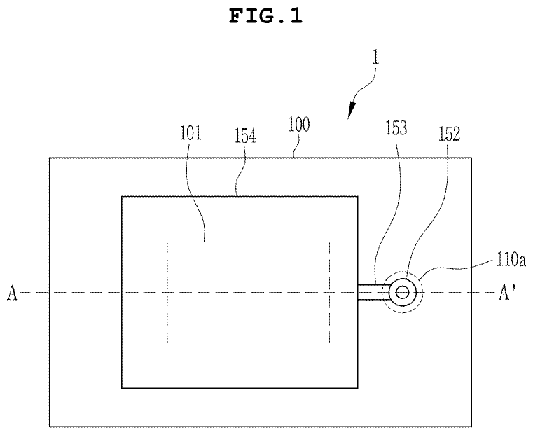

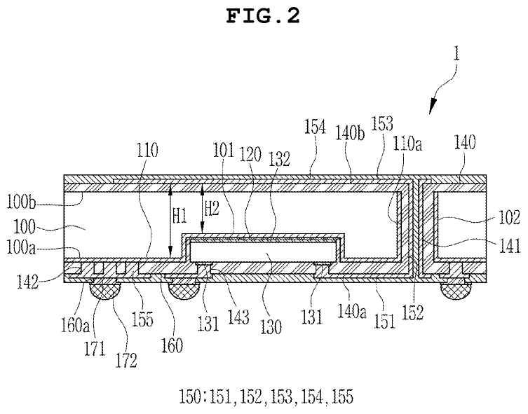

FIG. 1 is a plan view showing an antenna-integrated high-frequency semiconductor package 1 according to an embodiment. FIG. 2 is a cross-sectional view taken along line A-A′ of FIG. 1.

An antenna-integrated high-frequency semiconductor package 1 according to an embodiment may include a substrate 100 having a first surface 100a and a second surface 100b opposing the first surface 100a and including a recess 101 concave in the direction from the first surface 100a to the second surface 100b and a first through-hole 102 penetrating from the first surface 100a to the second surface 100b, a ground layer configured to cover the first surface 100a of the substrate 100 and the recess 101, a semiconductor chip 130 mounted on the ground layer 110 of the recess 101, an insulating layer 140 configured to entirely cover the substrate 100, the ground layer 110, and the semiconductor chip 130, and a conductive layer 150 formed on the insulating layer 140. Here, the conductive layer 150 may include an electrode pattern 151 formed on a first surface 140a of the insulating layer 140 and connected to the semiconductor chip 130, an antenna 154 formed on a second surface 140b of the insulating layer 140, and a signal via 152 configured to transmit an electrical signal between the electrode pattern 151 and the antenna 154 through a second through-hole 141 formed in the first through-hole 102 to penetrate from the first surface 140a to the second surface 140b of the insulating layer 140. The conductive layer 150 may further include a feed pattern 153 configured to connect the antenna 154 and the signal via 152.

The antenna-integrated high-frequency semiconductor package 1 according to an embodiment is a package that includes a semiconductor chip 130 that operates in a high frequency band and an antenna 154 capable of transmitting and receiving a high frequency signal. Since the semiconductor chip 130 is disposed on the first surface 100a of the substrate 100 and the antenna 154 is disposed on the second surface 100b of the substrate 100, the area of the package may be minimized. Briefly, the semiconductor chip 130 and the antenna 154 are arranged top and bottom in one package, thereby minimizing the area of the package.

The substrate 100 may be formed of silicon. The substrate 100 may have the first surface 100a and the second surface 100b opposing the first surface 100a.

The recess 101 may be formed in the first surface 100a of the substrate 100. The recess 101 may be formed by removing part of the first surface 100a of the substrate 100. The recess 101 may be formed in a size corresponding to the semiconductor chip 130. At least one recess 101 may be formed in the substrate 100.

The first through-hole 102 may be formed to penetrate from the first surface 100a to the second surface 100b of the substrate 100. At least one first through-hole 102 may be formed. The first through-hole 102 may be disposed adjacent to the recess 101.

The ground layer 110 may be formed on the first surface 100a of the substrate 100 and the inner surface 101a of the recess 101. The ground layer 110 may be formed of an electrically conductive material. The ground layer 110 may be formed of copper (Cu), aluminum (Al), silver (Ag), an electrically conductive metal, an alloy containing the same, a carbon-based material, etc. The ground layer 110 may be formed at a uniform thickness along the first surface 100a of the substrate 100 and the inner surface 101a of the recess 101.

The semiconductor chip 130 may process signals in high frequency bands. The semiconductor chip 130 may include a communication chip. At least one front pad 131 may be formed on the front surface (active surface) of the semiconductor chip 130. A back pad 132 may be formed on the back surface (inactive surface) of the semiconductor chip 130. There may be no pad on the back surface of the semiconductor chip 130. The semiconductor chip 130 may be mounted in the recess 101 so that the back surface thereof faces the ground layer 110. Specifically, the semiconductor chip 130 may be mounted in the recess 101 so that the front surface of the semiconductor chip 130 faces the same direction as the first surface 100a of the substrate 100.

As a comparative example, a package with a face-up structure in which the front surface of the semiconductor chip faces the antenna may integrate the antenna using an interposer structure without an additional insulating layer for the antenna, but there are difficulties in mounting the final package on an external circuit due to the height of the semiconductor chip. As another comparative example, when a semiconductor chip is configured face-down, an additional ground shielding layer and a thick insulating layer are needed for the antenna, which is likely to cause warpage of the final package. In contrast, according to an embodiment, the semiconductor chip 130 is embedded in the first surface 100a of the substrate 100, the antenna 154 is formed on the second surface 100b thereof, and the ground layer 110 is formed on the first surface 100a of the substrate 100, and thus, there is no need to form an additional ground or thick insulating layer on the second surface 100b of the substrate 100 for the antenna 154.

The semiconductor chip 130 may be mounted on the ground layer 110 formed on the inner surface 101a of the recess 101. An adhesive layer 120 may be further formed between the semiconductor chip 130 and the ground layer 110. The adhesive layer 120 may be formed of an electrically insulating material. The adhesive layer 120 may serve to fix the semiconductor chip 130 to the ground layer 110. The adhesive layer 120 may serve to transfer heat generated by the semiconductor chip 130 to the ground layer 110. The adhesive layer 120 may be formed of an electrically conductive material and may electrically connect the back pad 132 of the semiconductor chip 130 and the ground layer 110 to each other.

The insulating layer 140 may be formed to entirely cover the substrate 100, the ground layer 110, and the semiconductor chip 130. The insulating layer 140 may be formed of an electrically insulating material. The insulating layer 140 may entirely cover the first surface 100a of the substrate 100 and may also entirely cover the second surface 100b of the substrate 100. The insulating layer 140 may cover the ground layer 110 formed on the first surface 100a of the substrate 100. The insulating layer 140 may also cover the front surface of the semiconductor chip 130 and between the semiconductor chip 130 and the recess 101. The insulating layer 140 may be loaded in the first through-hole 102. The second through-hole 141 may be formed in the insulating layer 140 loaded in the first through-hole 102. The second through-hole 141 may penetrate from the first surface 140a to the second surface 140b of the insulating layer 140. The second through-hole 141 may be formed coaxially with the first through-hole 102.

The conductive layer 150 may be formed on the insulating layer 140. The conductive layer 150 may be formed of an electrically conductive material. The conductive layer 150 may be formed of copper (Cu), aluminum (Al), silver (Ag), an electrically conductive metal, an alloy containing the same, a carbon-based material, etc. The conductive layer 150 may include at least one electrode pattern 151, at least one antenna 154, and at least one signal via 152. The conductive layer 150 may include a feed pattern 153. The conductive layer 150 may be formed in a manner in which a metal layer is formed and patterned on the insulating layer 140.

The electrode pattern 151 may be formed on the first surface 140a of the insulating layer 140. The insulating layer 140 may include a pad open portion 143 exposing the front pad 131 of the semiconductor chip 130. The electrode pattern 151 may be connected to the front pad 131 of the semiconductor chip 130 by passing through the insulating layer 140 via the pad open portion 143. The electrode pattern 151 may electrically connect the semiconductor chip 130 and another semiconductor chip, the semiconductor chip 130 and the signal via 152, or the semiconductor chip 130 and an external circuit to each other.

The antenna 154 may be formed on the second surface 140b of the insulating layer 140. The antenna 154 may be connected to the signal via 152 through the feed pattern 153. The feed pattern 153 may also be formed by patterning the conductive layer 150.

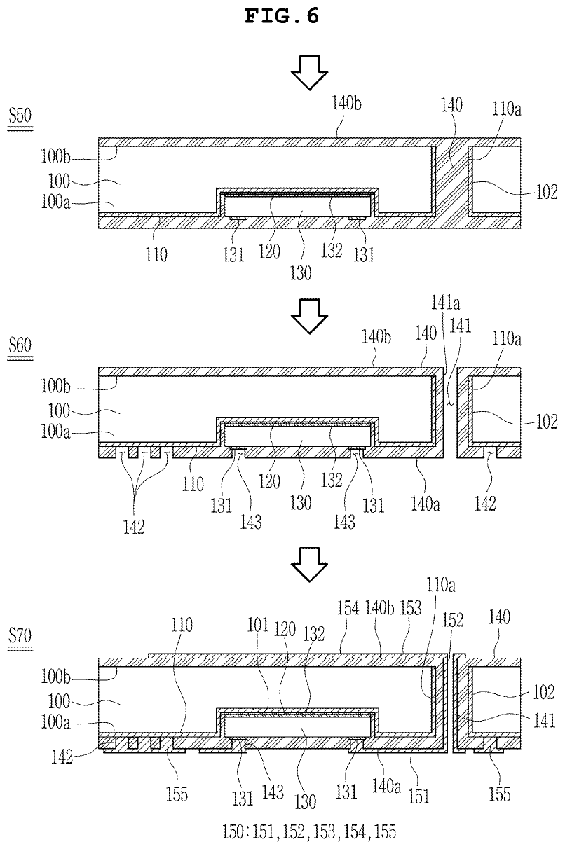

The signal via 152 may be a conductive layer 150 formed along the inner surface 141a (FIG. 6) of the second through-hole 141. The signal via 152 may transmit a signal output from the semiconductor chip 130 to the antenna 154. The signal via 152 may be formed to fill the entire interior of the second through-hole 141. The signal via 152 shown in FIG. 2 is provided in the form of a layer on the inner surface 141a of the second through-hole 141. Since the electrical signal output from the semiconductor chip 130 is a signal in a high frequency band, it flows along the surface of the signal via 152 due to the skin effect, so even the cylindrical signal via 152 provided in the form of a layer may efficiently transmit the electrical signal.

A protective layer 160 may be formed on the first surface 140a and the second surface 140b of the insulating layer 140 to cover the conductive layer 150. The protective layer 160 may protect the conductive layer 150 including the electrode pattern 151, the ground pattern 155, and the antenna 154 from damage. A bump hole 160a exposing the electrode pattern 151 may be formed in the protective layer 160. A solder bump metal 171 may be connected to the electrode pattern 151 through the bump hole 160a formed in the protective layer 160. Solder 172 may be formed on the solder bump metal 171. The antenna-integrated high-frequency semiconductor package 1 may be mounted on an external circuit using solder 172.

The antenna 154 may be a patch antenna using a microstrip structure. The antenna 154 may be designed in consideration of a first distance H1 from the ground layer 110 formed on the first surface 100a of the substrate 100 to the second surface 140b of the insulating layer 140, and a second distance H2 from the ground layer 110 formed on the inner surface 101a of the recess 101 to the second surface 140b of the insulating layer 140. Here, the first distance H1 may be the distance from the ground layer 110 formed on the first surface 100a of the substrate 100 to the antenna 154, and the second distance H2 may be the distance H2 from the ground layer 110 formed in the recess to the antenna 154. Since the recess is formed concavely in the first surface 100a of the substrate 100, the first distance H1 and the second distance H2 are different from each other.

Performance of the antenna 154 to transmit and receive radio waves is affected by the adjacent ground layer 110. The ground layer 110 is provided in the form of a layer along the first surface 100a of the substrate 100 and the recess 101. Some region of the antenna 154 may have a first distance H1 from the ground layer 110, and the other region of the antenna 154 may have a second distance H2 from the ground layer 110. The shape of some region of the antenna 154 with the first distance H1 from the ground layer 110 may be different from the shape of the other region of the antenna 154 with the second distance H2 from the ground layer 110. Therefore, in order for the antenna 154 to have the desired characteristics, the antenna has to be designed in consideration of the first distance H1 and the second distance H2, the shape of the region with the first distance H1, and the shape of the region with the second distance H2.

In order to accommodate a plurality of semiconductor chips 130, a plurality of recesses 101 may be formed in the substrate 100. The plurality of semiconductor chips 130 may have different sizes and thicknesses. Therefore, factors that must be considered when designing the antenna 154 include various heights and shapes of the recesses 101, the arrangement of the recesses 101, and the like.

The antenna-integrated high-frequency semiconductor package 1 according to an embodiment may further include a shield 110a formed on the inner surface 102a of the first through-hole 102 by forming the ground layer 110 to cover the inner surface 102a of the first through-hole 102, and the signal via 152 and the shield 110a may be formed as coaxial vias.

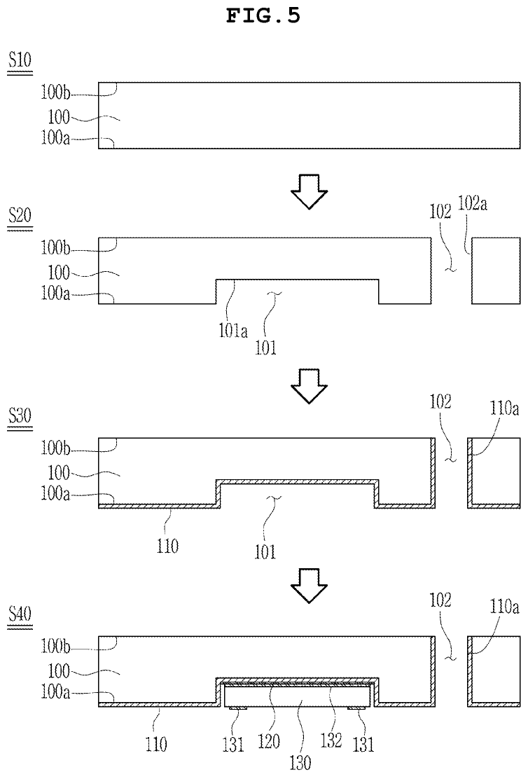

The ground layer 110 may be provided in the form of a layer that covers the inner surface 102a (FIG. 5) of the first through-hole 102. The ground layer 110 formed on the inner surface 102a of the first through-hole 102 may be the shield 110a of the coaxial vias. The shield 110a may be formed on the inner surface 102a of the first through-hole 102, the insulating layer 140 may be formed within the shield 110a, the second through-hole 141 within the insulating layer 140 may be formed coaxially with the first through-hole 102, and the signal via 152 may be formed within the second through-hole 141, whereby the signal via 152 and the shield 110a may form coaxial vias. The signal via 152 may be the core of the coaxial vias. The shield 110a is part of the ground layer 110 and is integrally connected, so it may have a ground potential.

Since the semiconductor chip 130 and the antenna 154 are integrated on one substrate 100, a feed structure for the antenna 154 having a very short electrical length may be provided. Since the high frequency signal output from the semiconductor chip 130 is transmitted to the antenna 154 along the coaxial vias, a feed structure with very low loss may be provided. The feed pattern 153 may be designed to have a minimum distance. Depending on the design, the feed pattern 153 may be omitted.

The antenna-integrated high-frequency semiconductor package 1 according to an embodiment may further include a ground pattern 155 configured to connect the ground layer 110 and an external circuit to each other by passing through the first surface 140a of the insulating layer 140 and dissipate heat generated by the semiconductor chip 130 to an external circuit.

The ground pattern 155 may be formed on the first surface 140a of the insulating layer 140. A ground open portion 142 exposing part of the ground layer 110 may be formed in the insulating layer 140. The ground open portion 142 may be formed by removing part of the insulating layer 140. The ground pattern 155 may be connected to the ground layer 110 through the ground open portion 142.

The ground pattern 155 may dissipate heat transferred to the ground layer 110 to an external circuit or a heat sink. Since the ground layer 110 is formed along the first surface 100a of the substrate 100, heat generated by the semiconductor chip 130 may be diffused and discharged along the ground layer 110. The ground pattern 155 may be disposed adjacent to the semiconductor chip 130 to thus quickly discharge heat from the semiconductor chip 130. A plurality of ground patterns 155 may be formed, so that a lot of heat may be discharged simultaneously.

The ground pattern 155 may be connected to the ground of an external circuit. A bump hole 160a exposing the ground pattern 155 may be formed in the protective layer 160, and a solder bump metal 171 may be connected to the ground pattern 155 through the bump hole 160a of the protective layer 160. Solder 172 may be formed on the solder bump metal 171, and the solder 172 may be connected to an external circuit to discharge heat from the ground pattern 155 and provide a ground potential.

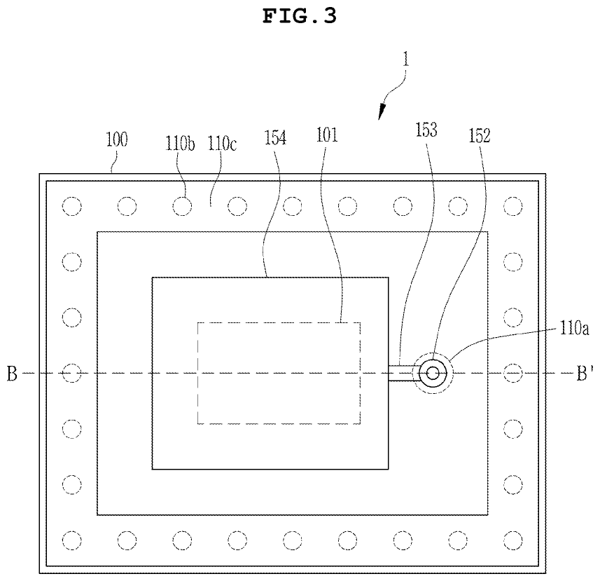

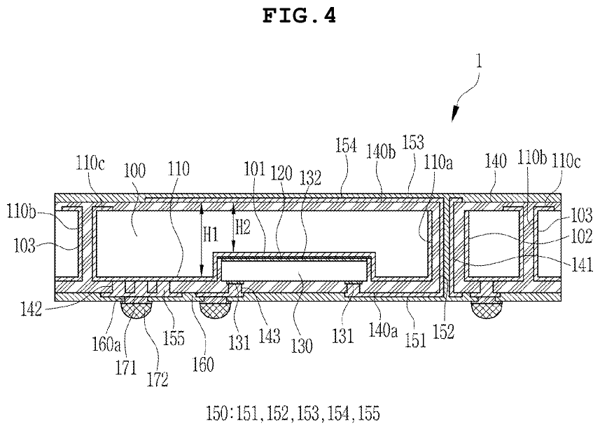

FIG. 3 is a plan view showing an antenna-integrated high-frequency semiconductor package 1 further including a ground ring 110c according to an embodiment. FIG. 4 is a cross-sectional view taken along line B-B′ of FIG. 3.

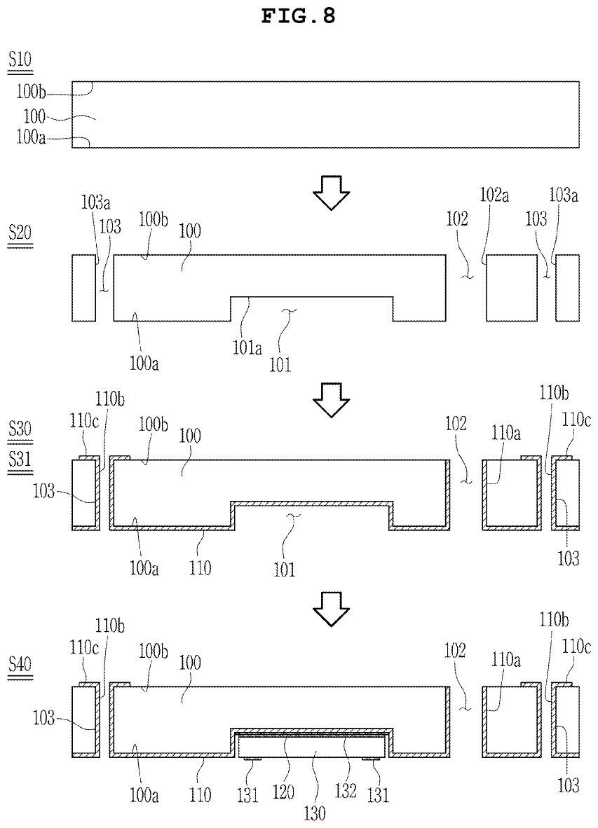

The antenna-integrated high-frequency semiconductor package 1 according to an embodiment may further include a third through-hole 103 formed to penetrate from the first surface 100a to the second surface 100b of the substrate 100, a ground via 110b formed on the inner surface 103a of the third through-hole 103 by forming the ground layer 110 to cover the inner surface 103a (FIG. 8) of the third through-hole 103, and a ground ring 110c connected to the ground via 110b and formed in a ring shape surrounding the antenna 154 by forming the ground layer 110 to cover the second surface 100b of the substrate 100 in a ring shape.

As the antenna-integrated high-frequency semiconductor package 1 according to an embodiment further includes a ground ring 110c formed on the second surface 100b of the substrate 100, the antenna 154 may be used in a G-CPW patch antenna structure. A plurality of third through-holes 103 connected to the ground ring 110c may be formed. Corresponding to the ground ring 110c being formed to surround the antenna 154, the plurality of third through-holes 103 may also be spaced apart from each other and arranged to surround the antenna 154.

The third through-holes 103 may be formed to penetrate from the first surface 100a to the second surface 100b of the substrate 100. The third through-holes 103 may be arranged to be spaced apart from each other along the edge of the package. Specifically, depending on the design of the G-GPW patch antenna, the third through-holes 103 may be formed in the region where the necessary ground ring 110c is to be formed.

The ground layer 110 may be formed on the inner surface 103a of the third through-hole 103, forming a ground via 110b. The ground via 110b is a ground layer 110 formed on the inner surface 103a of the third through-hole 103. Since the ground via 110b is integrally connected to the ground layer 110, it may have a ground potential. The ground via 110b allows the ground layer 110 on the first surface 100a of the substrate 100 to extend to the second surface 100b of the substrate 100.

The ground ring 110c may be connected to the ground via 110b. The ground layer 110 may extend to the second surface 100b of the substrate 100, forming a ground ring 110c. The ground ring 110c may be formed at a predetermined width and length to surround the antenna 154. In FIG. 3, the antenna 154 is in the shape of a square patch, and the ground ring 110c is in the shape of a square ring. The ground ring 110c may connect a plurality of ground vias 110b. Since the ground ring 110c and the ground via 110b are connected to the ground layer 110, they may receive a ground potential from an external circuit through the ground pattern 155.

The antenna-integrated high-frequency semiconductor package 1 according to an embodiment described above may be configured such that the semiconductor chip 130 and the antenna 154 are integrated on one substrate 100, achieving a short feed length, minimizing signal loss, and effectively dissipating heat of the semiconductor chip 130.

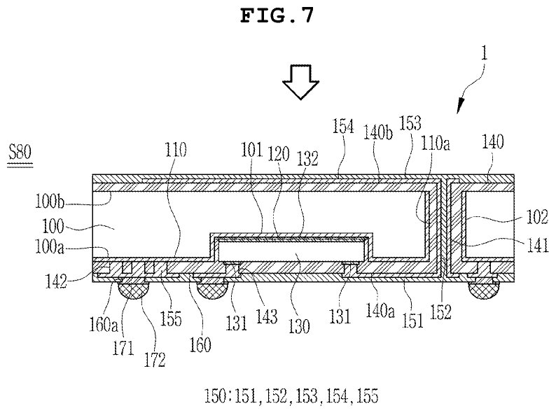

FIGS. 5, 6, and 7 show steps of a process of manufacturing an antenna-integrated high-frequency semiconductor package according to an embodiment.

A method of manufacturing an antenna-integrated high-frequency semiconductor package according to an embodiment may include preparing a substrate 100 having a first surface and a second surface opposing the first surface (S10), processing the substrate 100 to form a recess 101 concave in the direction from the first surface 100a to the second surface 100b of the substrate 100 and a first through-hole 102 penetrating from the first surface 100a to the second surface 100b (S20), forming a ground layer 110 with an electrically conductive material to cover the first surface 100a of the substrate 100 and the recess 101 (S30), mounting a semiconductor chip 130 in the recess 101 covered with the ground layer 110 (S40), forming an insulating layer 140 that entirely covers the substrate 100, the ground layer 110, and the semiconductor chip 130 (S50), processing the insulating layer 140 to form a pad open portion 143 exposing the front pad 131 of the semiconductor chip 130 by removing part of the insulating layer 140 and a second through-hole 141 in the first through-hole 102 to penetrate from the first surface 140a to the second surface 140b of the insulating layer 140 (S60), and forming a conductive layer 150 with an electrically conductive material on the first surface 140a and the second surface 140b of the insulating layer 140 and patterning the conductive layer 150 (S70). Here, patterning the conductive layer 150 (S70) may include forming an electrode pattern 151 connected to the semiconductor chip 130 by patterning the conductive layer 150 formed on the first surface 140a of the insulating layer 140, and forming an antenna 154 by patterning the conductive layer 150 formed on the second surface 140b of the insulating layer 140, and a signal via 152 formed on the inner surface 141a of the second through-hole 141 may be connected to transmit an electrical signal between the electrode pattern 151 and the antenna 154.

The method of manufacturing the antenna-integrated high-frequency semiconductor package according to an embodiment may be applied in a manner in which a unit package is manufactured by forming multiple packages on one wafer and cutting the same. Additionally, a detailed description of steps using known processes will be omitted. For sake of convenience, a description is based on the unit package.

Preparing the substrate 100 (S10) is a process of preparing the substrate 100 made of silicon.

Processing the substrate 100 (S20) is a process of forming the recess 101 and the through-hole in the substrate 100. In processing the substrate 100 (S20), the recess 101 concave in the direction from the first surface 100a to the second surface 100b of the substrate 100 may be formed by removing part of the first surface 100a of the substrate 100. In processing the substrate 100 (S20), the first through-hole 102 penetrating from the first surface 100a to the second surface of the substrate 100 may be formed. The recess 101 and the first through-hole 102 may be formed using a process such as wet or dry etching. It does not matter which of the recess 101 and the first through-hole 102 is formed first.

Forming the ground layer 110 (S30) is a process of forming a layer of an electrically conductive material such as metal on the substrate 100. In forming the ground layer 110 (S30), the ground layer 110 may be provided in the form of a layer on the first surface 100a of the substrate 100 and the inner surface 101a of the recess 101. In forming the ground layer 110 (S30), a shield 110a may be further formed on the inner surface 102a of the first through-hole 102 by forming the ground layer 110 to cover the inner surface 102a of the first through-hole 102. The ground layer 110 may be formed by deposition or plating from the first surface 100a toward the second surface 100b of the substrate 100.

Mounting the semiconductor chip 130 (S40) is a process of mounting the semiconductor chip 130 on the ground layer 110 formed in the recess 101. Before mounting the semiconductor chip 130, an adhesive layer 120 may be formed on the ground layer 110 in the recess 101, and the semiconductor chip 130 may be mounted so that the back surface of the semiconductor chip 130 is adhered to the adhesive layer 120. In mounting the semiconductor chip 130 (S40), a plurality of semiconductor chips 130 may be mounted in a plurality of recesses 101.

Forming the insulating layer 140 (S50) is a process of forming the insulating layer 140 over the first surface 100a and the second surface of the substrate 100 to entirely cover the substrate 100, the ground layer 110, and the semiconductor chip 130. In forming the insulating layer 140 (S50), the insulating layer 140 may be loaded between the recess 101 and the semiconductor chip 130 to fix the semiconductor chip 130. The insulating layer 140 may also be loaded inside the first through-hole 102, that is, inside the shield 110a.

Processing the insulating layer 140 (S60) is a process of removing part of the insulating layer 140. When part of the insulating layer 140 is removed in processing the insulating layer 140 (S60), the lower layer may be exposed. In processing the insulating layer 140 (S60), a pad open portion 143 exposing the front pad 131 of the semiconductor chip 130 may be formed by removing part of the insulating layer 140. The pad open portion 143 may be formed for each of a plurality of front pads 131.

In processing the insulating layer 140 (S60), the second through-hole 141 penetrating from the first surface 140a to the second surface 140b of the insulating layer 140 may be formed in the first through-hole 102. In processing the insulating layer 140 (S60), the first through-hole 102 and the second through-hole 141 may be formed coaxially, so that the signal via 152 and the shield 110a may be formed coaxially.

In processing the insulating layer 140 (S60), a ground open portion 142 exposing part of the ground layer 110 may be further formed by removing the first surface 140a of the insulating layer 140. A plurality of ground open portions 142 may be formed to expose various parts of the ground layer 110. The ground open portions 142 may be formed in a large area.

Forming and patterning the conductive layer 150 (S70) is a process of forming an electrode pattern 151, a ground pattern 155, a signal via 152, an antenna 154, and a feed pattern 153 on the insulating layer 140. In forming and patterning the conductive layer 150 (S70), a ground pattern 155 that connects the ground layer 110 and an external circuit to each other and dissipates heat generated by the semiconductor chip 130 to the external circuit may be further formed. Forming and patterning the conductive layer 150 (S70) may be performed by forming a layer of an electrically conductive material on the insulating layer 140, followed by removing specific part thereof and leaving the electrode pattern 151, etc. Alternatively, forming and patterning the conductive layer 150 (S70) may be performed in a manner in which a mask is formed on the insulating layer 140 to expose the region where the electrode pattern 151, etc. will be formed, an electrically conductive material is formed on the exposed insulating layer 140, and the mask is removed.

The ground pattern 155 may be formed to be spaced apart from the electrode pattern 151, the signal via 152, the antenna 154, and the feed pattern 153. This is because the electrode pattern 151, the signal via 152, the antenna 154, and the feed pattern 153 transmit electrical signals transferred by the semiconductor chip 130. The electrode pattern 151 connected to one of the front pads 131 of the semiconductor chip 130 may be connected to the second surface 140b of the insulating layer 140 through the signal via 152 and may be connected to the antenna 154 through the feed pattern 153. Since the first through-hole 102 and the second through-hole 141 are formed coaxially, the shield 110a formed on the inner surface 102a of the first through-hole 102 and the shield 110a formed on the inner surface 141a of the second through-hole 141 may be formed coaxially.

Patterning the conductive layer 150 (S70) may include patterning the antenna 154 in a shape designed in consideration of a first distance H1 from the ground layer 110 formed on the first surface 100a of the substrate 100 to the second surface 140b of the insulating layer 140 and a second distance H2 from the ground layer 110 formed on the inner surface 101a of the recess 101 to the second surface 140b of the insulating layer 140.

In forming the antenna 154 by patterning the conductive layer 150 formed on the second surface 140b of the insulating layer 140, the shape and size of the antenna 154 may be determined taking into consideration the distance to the ground layer 110. In patterning the conductive layer 150 (S70), desired performance may be achieved by patterning the antenna 154 depending on the design.

Forming a protective layer 160 (S80) is a process of forming a protective layer 160 on the insulating layer 140 to cover the conductive layer 150. The protective layer 160 may serve to electrically insulate and physically protect the conductive layer 150. After forming the protective layer 160, an exposure portion exposing the electrode pattern 151 or the ground pattern 155 may be further formed in the protective layer 160, and a solder bump metal 171 and solder 172 may be further formed on the exposure portion.

In the method of manufacturing the antenna-integrated high-frequency semiconductor package described above, the ground layer 110, which functions as the ground of the antenna 154 and the shield 110a of the coaxial vias, may be formed together while forming the ground layer 110, and the electrode pattern 151, the ground pattern 155, the signal via 152 of the coaxial vias, the feed pattern 153, and the antenna 154 may be formed together while forming the conductive layer 150. Therefore, the process is simplified, and multiple packages may be formed using a large-area wafer.

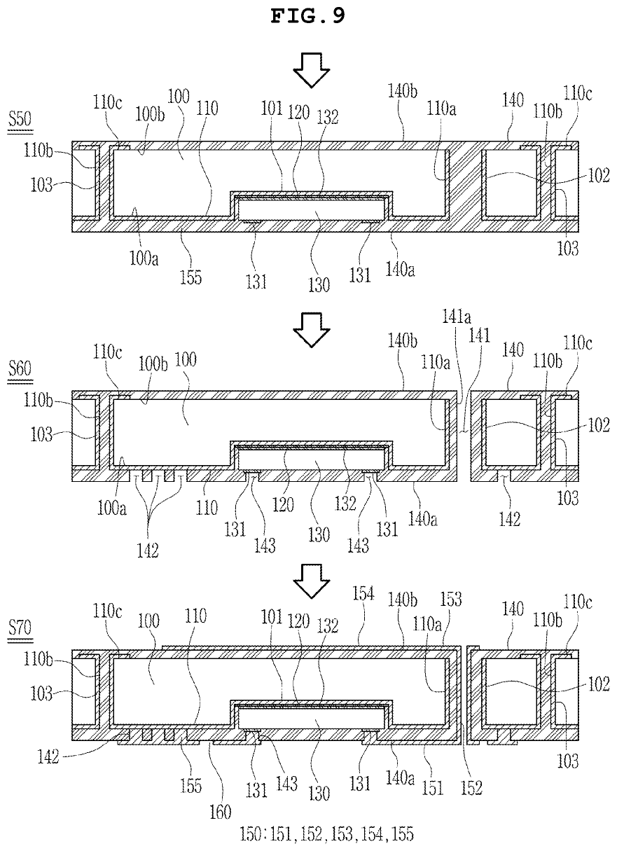

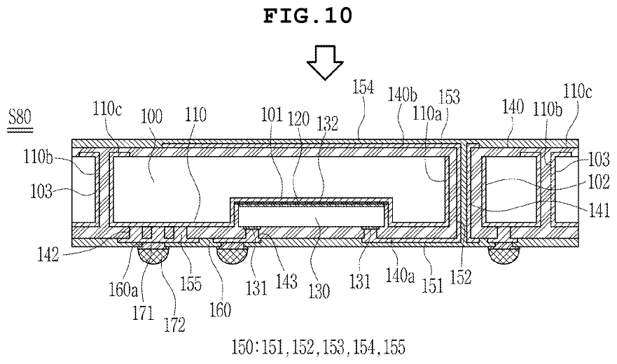

FIGS. 8, 9, and 10 show steps of a process of manufacturing an antenna-integrated high-frequency semiconductor package according to an embodiment.

The method of manufacturing the antenna-integrated high-frequency semiconductor package according to an embodiment may further include additional processes to further form a ground ring 110c.

In preparing a substrate 100 (S10), a substrate 100 made of silicon is prepared.

In processing the substrate 100 (S20), a third through-hole 103 may be further formed to penetrate from the first surface 100a to the second surface 100b of the substrate 100. Details of forming the recess 101 and the first through-hole 102 in processing the substrate 100 (S20) are as described above. The third through-hole 103 may be provided to form a ground via 110b connected to the ground ring 110c. A plurality of third through-holes 103 may be formed. A plurality of third through-holes 103 may be formed to surround the region where the antenna 154 will be formed. The third through-hole 103 may be formed simultaneously with formation of the second through-hole 141. The third through-hole 103 may be formed to penetrate from the first surface 100a to the second surface of the substrate 100 using etching or the like.

In forming a ground layer 110 (S30), a ground via 110b may be formed on the inner surface 103a of the third through-hole 103 by forming the ground layer 110 to cover the inner surface 103a of the third through-hole 103, and the ground layer 110 may be formed to cover the second surface 100b of the substrate 100.

In forming the ground layer 110 (S30), the ground layer 110 may be formed to cover not only the first surface 100a of the substrate 100, the inner surface 101a of the recess 101, and the inner surface 102a of the first through-hole 102, but also the inner surface 103a of the third through-hole 103 and the second surface 100b of the substrate 100. The ground layer 110 covering the inner surface 103a of the third through-hole 103 may be a ground via 110b connecting the ground to the second surface 100b of the substrate 100.

The method of manufacturing the antenna-integrated high-frequency semiconductor package may further include forming a ground ring 110c to cover the second surface 100b of the substrate 100 in a ring shape by patterning the ground layer 110 formed on the second surface 100b of the substrate 100 (S31), after forming the ground layer 110 (S30). The ground ring 110c may be formed along the edge of the substrate.

Forming the ground ring 110c (S31) is a process of patterning the ground layer 110. The ground layer 110 formed on the second surface 100b of the substrate 100 may be patterned, leaving a ground ring 110c. As the ground layer 110 is formed, patterning is performed in a state in which a plurality of ground vias 110b is connected through the second surface 100b of the substrate 100, such that the ground vias 110b and the ground ring 110c are formed to surround the antenna 154.

Forming the ground ring 110c (S31) may be performed in a manner in which a mask is formed on the second surface 100b of the substrate 100 to cover the region where the ground layer 110 will not be formed, the ground layer 110 is formed, and the mask is removed.

After forming the ground layer 110, mounting a semiconductor chip 130 on the ground layer 110 in the recess 101 (S40) may be performed.

In forming an insulating layer 140 (S50), the insulating layer may be formed to cover the substrate 100, the ground layer 110, the semiconductor chip 130, and the ground ring 110c, and the insulating layer may be loaded inside the first through-hole 102 and inside the third through-hole 103.

In forming and patterning a conductive layer 150 (S70), an electrode pattern 151, a ground pattern 155, an antenna 154, a feed pattern 153, and a signal via 152 may be formed. In forming and patterning the conductive layer 150 (S70), the antenna 154 may be patterned to be spaced apart from the ground ring 110c, namely formed in a position surrounded by the ground ring 110c.

Forming a protective layer 160 (S80) is as described above and a description thereof is therefore omitted.

The method of manufacturing the antenna 154-integrated high-frequency semiconductor package described above may include forming the ground ring 110c surrounding the antenna 154 together while forming the ground layer 110. Therefore, the antenna 154 may be formed in a G-CPW patch antenna structure.

The present disclosure has been described in detail above through specific embodiments. The embodiments are for specifically explaining the present disclosure, and the present disclosure is not limited thereto. It will be clear that modifications and improvements may be made by those skilled in the art within the technical spirit of the present disclosure.

Simple modifications or variations of the present disclosure fall within the scope of the present disclosure as defined in the accompanying claims.

What is claimed is:

1. An antenna-integrated high-frequency semiconductor package, comprising:
a substrate having a first surface and a second surface opposing the first surface and comprising a recess concave in a direction from the first surface to the second surface and a first through-hole penetrating from the first surface to the second surface;
a ground layer configured to cover the first surface of the substrate and the recess;
a semiconductor chip mounted on the ground layer of the recess;
an insulating layer configured to entirely cover the substrate, the ground layer, and the semiconductor chip; and
a conductive layer formed on the insulating layer,
wherein the conductive layer comprises:
an electrode pattern formed on a first surface of the insulating layer and connected to the semiconductor chip;
an antenna formed on a second surface of the insulating layer; and
a signal via configured to transmit an electrical signal between the electrode pattern and the antenna through a second through-hole formed in the first through-hole to penetrate from the first surface to the second surface of the insulating layer.

2. The antenna-integrated high-frequency semiconductor package according to claim 1, wherein the antenna is designed in consideration of a first distance from the ground layer formed on the first surface of the substrate to the second surface of the insulating layer and a second distance from the ground layer formed on an inner surface of the recess to the second surface of the insulating layer.

3. The antenna-integrated high-frequency semiconductor package according to claim 1, further comprising a shield formed on an inner surface of the first through-hole by forming the ground layer to cover the inner surface of the first through-hole, wherein the signal via and the shield are formed as coaxial vias.

4. The antenna-integrated high-frequency semiconductor package according to claim 1, further comprising:
a third through-hole formed to penetrate from the first surface to the second surface of the substrate;
a ground via formed on an inner surface of the third through-hole by forming the ground layer to cover the inner surface of the third through-hole; and
a ground ring connected to the ground via and formed in a ring shape surrounding the antenna by forming the ground layer to cover the second surface of the substrate in a ring shape.

5. The antenna-integrated high-frequency semiconductor package according to claim 1, further comprising a ground pattern configured to connect the ground layer and an external circuit to each other by passing through the first surface of the insulating layer and dissipate heat generated by the semiconductor chip to an external circuit.

6. A method of manufacturing an antenna-integrated high-frequency semiconductor package, comprising:
preparing a substrate having a first surface and a second surface opposing the first surface;
processing the substrate to form a recess concave in a direction from the first surface to the second surface of the substrate and a first through-hole penetrating from the first surface to the second surface;
forming a ground layer with an electrically conductive material to cover the first surface of the substrate and the recess;
mounting a semiconductor chip in the recess covered with the ground layer;
forming an insulating layer that entirely covers the substrate, the ground layer, and the semiconductor chip;
processing the insulating layer to form a pad exposure portion exposing a front pad of the semiconductor chip by removing part of the insulating layer and a second through-hole in the first through-hole to penetrate from the first surface to the second surface of the insulating layer; and
forming a conductive layer with an electrically conductive material on the first surface and the second surface of the insulating layer and patterning the conductive layer,
wherein patterning the conductive layer comprises forming an electrode pattern connected to the semiconductor chip by patterning a conductive layer formed on the first surface of the insulating layer and forming an antenna by patterning a conductive layer formed on the second surface of the insulating layer, and a signal via formed on an inner surface of the second through-hole is connected to transmit an electrical signal between the electrode pattern and the antenna.

7. The method according to claim 6, wherein, in patterning the conductive layer, the antenna is patterned in a shape designed in consideration of a first distance from the ground layer formed on the first surface of the substrate to the second surface of the insulating layer and a second distance from the ground layer formed on an inner surface of the recess to the second surface of the insulating layer.

8. The method according to claim 6, wherein:
in forming the ground layer, a shield is further formed on an inner surface of the first through-hole by forming the ground layer to cover the inner surface of the first through-hole, and
in processing the insulating layer, the first through-hole and the second through-hole are formed coaxially, so that the signal via and the shield are formed coaxially.

9. The method according to claim 6, wherein:
in processing the substrate, a third through-hole is further formed to penetrate from the first surface to the second surface of the substrate,
in forming the ground layer, a ground via is formed on an inner surface of the third through-hole by forming the ground layer to cover the inner surface of the third through-hole, and the ground layer is formed to cover the second surface of the substrate, and
the method of manufacturing the antenna-integrated high-frequency semiconductor package further comprises forming a ground ring to cover the second surface of the substrate in a ring shape by patterning the ground layer formed on the second surface of the substrate, after forming the ground layer.

10. The method according to claim 6, wherein:
in processing the insulating layer, a ground exposure portion exposing part of the ground layer is further formed by removing the first surface of the insulating layer, and
in patterning the conductive layer, a ground pattern that connects the ground layer and an external circuit to each other and dissipates heat generated by the semiconductor chip to an external circuit is further formed.
